(19) United States
(12) Patent Application Publication
(10) Pub. No.: US 2026/0247616 A1
(43) Pub. Date: Aug. 20, 2026

(54) SEMICONDUCTOR STORAGE DEVICE AND MANUFACTURING METHOD THEREOF

(71) Applicant: Kioxia Corporation, Tokyo (JP)

(72) Inventors: Hiroya MURANISHI, Mie (JP); Teruhisa SONOHARA, Yokkaichi (JP)

(73) Assignee: Kioxia Corporation, Tokyo (JP)

(21) Appl. No.: 19/237,185

(22) Filed: Jun. 13, 2025

(30) Foreign Application Priority Data
Feb. 19, 2025 (JP) 2025-025013

(51) Int. Cl. H10B 43/27; H10B 43/35

(52) U.S. Cl. CPC H10B 43/27; H10B 43/35

(57) ABSTRACT

A semiconductor storage device according to the present embodiment includes a stacked body and a column. The stacked body is made up of a plurality of first conductive layers stacked. The column extends by penetrating through the stacked body. The column includes a semiconductor layer and a memory film. The semiconductor layer extends by penetrating through the stacked body. The memory film includes a first insulator, a charge trap layer, and a second insulator provided between the stacked body and the semiconductor layer. The semiconductor storage device further includes a second conductive layer electrically connected with the semiconductor layer at an end of the column. At least one crystal grain in the semiconductor layer is shaped to contact the memory film. The semiconductor layer has a first opening at the end of the column or a grain boundary exists in the semiconductor layer at the end of the column.

### CROSS REFERENCE TO RELATED APPLICATIONS

This application is based upon and claims the benefit of priority from the prior Japanese Patent Application No. 2025-025013, filed on February 19, 2025, the entire contents of which are incorporated herein by reference.

### FIELD

The embodiments of the present invention relate to a semiconductor storage device and a manufacturing method thereof.

### BACKGROUND

Characteristics of a channel semiconductor layer of a semiconductor memory have a great impact on memory cell performance. For example, low mobility of the channel semiconductor layer will increase a threshold voltage of memory cells resulting in an increased operation voltage of the memory cells.

### BRIEF DESCRIPTION OF THE DRAWINGS

FIG. 1 is a cross-sectional view showing an exemplary configuration of a semiconductor storage device according to a first embodiment;

FIG. 2A is a cross-sectional view showing an example of a manufacturing method for the semiconductor storage device according to the first embodiment;

FIG. 2B is a cross-sectional view showing the example of the manufacturing method for the semiconductor storage device, continuing from FIG. 2A;

FIG. 2C is a cross-sectional view showing the example of the manufacturing method for the semiconductor storage device, continuing from FIG. 2B;

FIG. 3A is a cross-sectional view showing an example of the manufacturing method for the semiconductor storage device according to the first embodiment;

FIG. 3B is a cross-sectional view showing the example of the manufacturing method for the semiconductor storage device, continuing from FIG. 3A;

FIG. 3C is a cross-sectional view showing the example of the manufacturing method for the semiconductor storage device, continuing from FIG. 3B;

FIG. 3D is a cross-sectional view showing the example of the manufacturing method for the semiconductor storage device, continuing from FIG. 3C;

FIG. 3E is a cross-sectional view showing the example of the manufacturing method for the semiconductor storage device, continuing from FIG. 3D;

FIG. 3F is a cross-sectional view showing the example of the manufacturing method for the semiconductor storage device, continuing from FIG. 3E;

FIG. 3G is a cross-sectional view showing the example of the manufacturing method for the semiconductor storage device, continuing from FIG. 3F;

FIG. 4A is a cross-sectional view showing an example of a manufacturing method for a semiconductor storage device according to a modification of the first embodiment;

FIG. 4B is a cross-sectional view showing the example of the manufacturing method for the semiconductor storage device, continuing from FIG. 4A;

FIG. 5A is a cross-sectional view showing an example of a manufacturing method for a semiconductor storage device according to a second embodiment;

FIG. 5B is a cross-sectional view showing the example of the manufacturing method for the semiconductor storage device, continuing from FIG. 5A;

FIG. 5C is a cross-sectional view showing the example of the manufacturing method for the semiconductor storage device, continuing from FIG. 5B;

FIG. 5D is a cross-sectional view showing the example of the manufacturing method for the semiconductor storage device, continuing from FIG. 5C; and

FIG. 5E is a cross-sectional view showing the example of the manufacturing method for the semiconductor storage device, continuing from FIG. 5D.

### DETAILED DESCRIPTION

Embodiments will now be explained with reference to the accompanying drawings. The present invention is not limited to the embodiments. It should be noted that the drawings are schematic or conceptual, and the relationship between the thickness and the width in each element and the ratio among the dimensions of elements do not necessarily match the actual ones. Even if two or more drawings show the same portion, the dimensions and the ratio of the portion may differ in each drawing. In the present specification and the drawings, elements identical to those described in the foregoing drawings are denoted by like reference characters and detailed explanations thereof are omitted as appropriate.

A semiconductor storage device according to the present embodiment includes a stacked body and a column. The stacked body is made up of a plurality of first conductive layers stacked in a first direction via an insulation layer. The column extends in the first direction by penetrating through the stacked body. The column includes a semiconductor layer and a memory film. The semiconductor layer extends in the first direction by penetrating through the stacked body. The memory film includes a first insulator, charge trap layer, and a second insulator provided between the stacked body and the semiconductor layer. The semiconductor storage device further includes a second conductive layer electrically connected with the semiconductor layer at an end of the column. At least one crystal grain in the semiconductor layer is shaped to contact the memory film. The semiconductor layer has a first opening at the end of the column or a grain boundary exists in the semiconductor layer at the end of the column.

### First embodiment

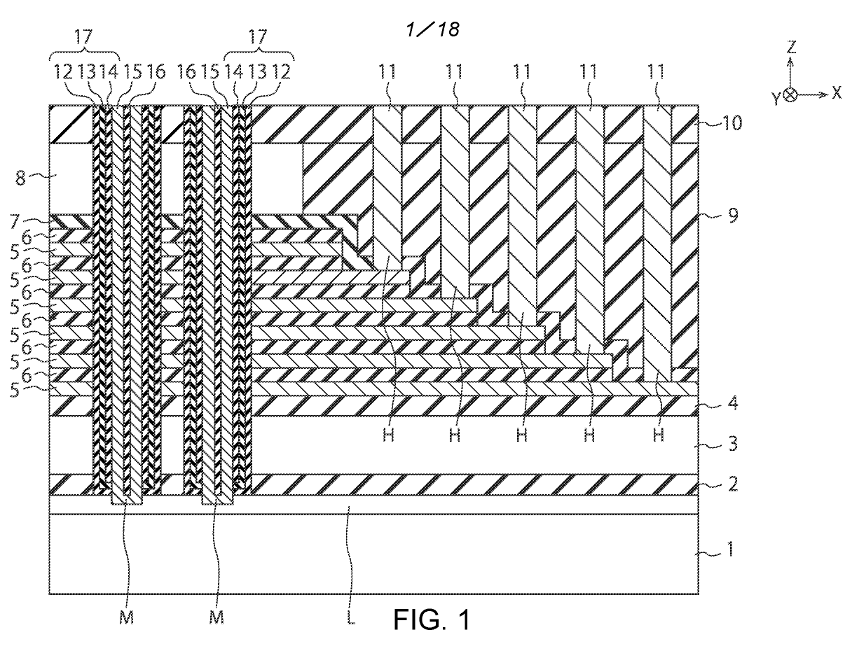

FIG. 1 is a cross-sectional view showing an exemplary configuration of a semiconductor storage device according to a first embodiment. The semiconductor storage device in FIG. 1 includes a three-dimensional semiconductor memory.

The semiconductor storage device in FIG. 1 includes a substrate 1, a lower insulator 2, a source-side conductive layer 3, an upper insulator 4, a plurality of electrode layers 5, a plurality of insulation layers 6, a cover insulator 7, a drain-side conductive layer 8, a first interlayer insulator 9, a second interlayer insulator 10, a plurality of contact plugs 11, a block insulator 12, which is an example of a second insulator, a charge trap layer 13, a tunnel insulator 14, which is an example of a first insulator, a channel semiconductor layer 15, and a core insulator 16, which is an example of a third insulator.

The substrate 1 is, for example, a semiconductor substrate such as a Si (silicon) substrate. FIG. 1 shows an X direction and Y direction parallel to a surface of the substrate 1 and perpendicular to each other as well as shows a Z direction perpendicular to the surface of the substrate 1. Hereinafter, a +Z direction is treated as an upward direction and -Z direction is treated as a downward direction. The -Z direction may or may not coincide with the gravity direction. The Z direction is an example of the first direction.

The lower insulator 2 is formed on a diffusion layer L formed in the substrate 1. The source-side conductive layer 3 is formed on the lower insulator 2. The upper insulator 4 is formed on the source-side conductive layer 3.

The plurality of electrode layers 5 and the plurality of insulation layers 6 are stacked alternately in the Z direction on the upper insulator 4. The electrode layers 5 are conductive layers such as metal layers and function as word lines or selection lines. The number of electrode layers 5 is, for example, 64 or above. The insulation layers 6 are, for example, SiO₂ films (silicon oxide films). The number of insulation layers 6 is, for example, 64 or above. FIG. 1 shows memory holes M penetrating through the electrode layers 5 and the insulation layers 6 as well as shows contact holes H formed on a stepwise region of the electrode layers 5 and insulation layers 6.

The cover insulator 7 is formed on the stacked body, which includes the electrode layers 5 and the insulation layers 6. The drain-side conductive layer 8 is formed on the cover insulator 7, being placed adjacent to the stepwise region. The first interlayer insulator 9 is formed on the cover insulator 7 by being embedded in the space in the stepwise region. The second interlayer insulator 10 is formed on the drain-side conductive layer 8 and the first interlayer insulator 9.

The plurality of contact plugs 11 are formed in the contact holes H that penetrate through the cover insulator 7, the first interlayer insulator 9, and the second interlayer insulator 10. The contact plugs 11 are electrically connected to different electrode layers 5, respectively. The contact plugs 11 are formed, for example, of a barrier metal layer such as Ti (titanium)-containing layer or a plug material layer such as a W (tungsten) layer.

The block insulator 12, the charge trap layer 13, the tunnel insulator 14, the channel semiconductor layer 15, and the core insulator 16 are formed in order on a lateral surface of each memory hole M that penetrates through the lower insulator 2, the source-side conductive layer 3, the upper insulator 4, the electrode layers 5, the insulation layers 6, the cover insulator 7, the drain-side conductive layer 8, and the second interlayer insulator 10. The block insulator 12 is, for example, a SiO₂ film. The charge trap layer 13 is, for example, a SiN film (silicon nitride film), but may be a semiconductor layer such as a polysilicon layer or a polysilicon germanium layer. The tunnel insulator 14 is, for example, a SiO₂ film. The channel semiconductor layer 15 is, for example, a polysilicon layer or a polysilicon germanium layer, and is electrically connected to the substrate 1. The core insulator 16 is, for example, a SiO₂ film. Reference sign 17 denotes a memory film that includes the block insulator 12, the charge trap layer 13, and the tunnel insulator 14. The core insulator 16 generally has a columnar shape that extends in the Z direction. The channel semiconductor layer 15, the tunnel insulator 14, the charge trap layer 13, and the block insulator 12 generally have a cylindrical shape extending in the Z direction, and surround the core insulator 16 in order.

The block insulator 12, the charge trap layer 13, the tunnel insulator 14, the channel semiconductor layer 15, and the core insulator 16 are formed, for example, using the following procedures. First, the block insulator 12, the charge trap layer 13, and the tunnel insulator 14 are formed in order on the lateral surface and a bottom surface of the memory hole M. Next, the tunnel insulator 14, the charge trap layer 13, and the block insulator 12 are removed from the bottom surface of the memory hole M. Subsequently, the channel semiconductor layer 15 and the core insulator 16 are embedded in the memory hole M in order.

Next, details of the channel semiconductor layer 15 and the tunnel insulator 14 according to the present embodiment will be described.

The channel semiconductor layer 15 according to the present embodiment contains trace amounts of metal atoms. The concentration of metal atoms in the channel semiconductor layer 15 is, for example, 4.0 × 10¹⁷ [atoms/cm³] or below. According to the present embodiment, the metal atoms are distributed almost uniformly in the channel semiconductor layer 15. The metal atoms are, for example, Ni (nickel) atoms. According to the present embodiment, the film thickness of the tunnel insulator 14 is, for example, between 5 nm and 10 nm (both inclusive), and the film thickness of the channel semiconductor layer 15 is, for example, 15 nm or below (preferably 10 nm or below).

According to the present embodiment, a film containing metal atoms is formed on a surface of the channel semiconductor layer 15 (a semiconductor layer 21 described later) yet to be crystallized, and then the channel semiconductor layer 15 is crystallized. This makes it possible to crystallize the channel semiconductor layer 15 at low temperature, and thereby increase the grain size of crystal grains in the channel semiconductor layer 15. This in turn makes it possible to increase the mobility of the channel semiconductor layer 15 and thereby reduce a threshold voltage of memory cells of a three-dimensional semiconductor memory. During the crystallization of the channel semiconductor layer 15, the metal atoms enter the channel semiconductor layer 15.

By forming a film containing metal atoms on the surface of the yet-to-be crystallized channel semiconductor layer 15 before crystallizing the channel semiconductor layer 15, the present embodiment makes it possible to keep the grain size of the crystal grains in the channel semiconductor layer 15, for example, between 80 nm and 1600 nm (both inclusive). Such a grain size can be realized, for example, by forming, on the surface of the channel semiconductor layer 15, a film containing such a quantity of metal atoms that the concentration of metal atoms in the channel semiconductor layer 15 will be 5.0 × 10¹⁷ [atoms/cm³] or above.

Furthermore, according to the present embodiment, after crystallization of the channel semiconductor layer 15, part of the metal atoms in the channel semiconductor layer 15 is removed. This makes it possible to reduce the concentration of metal atoms in the channel semiconductor layer 15 to or below 4.0 × 10¹⁷ [atoms/cm³] as described above.

The concentration of 5.0 × 10¹⁷ [atoms/cm³] or above before the removal of metal atoms makes it possible to realize a grain size of, for example, between 80 nm and 1600 nm (both inclusive). On the other hand, the concentration of 4.0 × 10¹⁷ [atoms/cm³] or below after the removal of metal atoms makes it possible to reduce, for example, a leakage current in the tunnel insulator 14 compared to when metal atoms are not removed.

The metal atoms according to the present embodiment are, for example, Ni atoms, but may be other metal atoms. Desirably, the metal atoms according to the present embodiment include, atoms of at least any of, for example, Au (gold), Al (aluminum), Cu (copper), Ag (silver), Pd (palladium), Ni (nickel), and Pt (platinum) (first example). Alternatively, the metal atoms according to the present embodiment may include atoms of at least any of, for example, Mn (manganese), Rh (rhodium), Co (cobalt), Fe (iron), Cr (chromium), Ti (titanium), Nb (niobium), Ir (iridium), Ta (tantalum), Re (rhenium), Mo (molybdenum), V (vanadium), Hf (hafnium), Ru (ruthenium), Zr (zirconium), and W (tungsten) (second example). Both the metal atoms of the first example and the metal atoms of the second example have the effect of reducing crystallization temperature of the channel semiconductor layer 15, but the effect of the first example is generally greater than the second example.

The use of Al or Ti has the advantage of, for example, being able to form an insulator on the surface of the channel semiconductor layer 15 if oxidation treatment or nitriding treatment is performed after crystallization of the channel semiconductor layer 15. The existence of Al or Ti in the channel semiconductor layer 15 might deteriorate short channel characteristics of the tunnel insulator 14 or the channel semiconductor layer 15. However, if the channel semiconductor layer 15 containing Al is oxidized or nitrided, an AlO_{X} film or an AiN film will be formed as an insulator on the surface of the channel semiconductor layer 15, making it possible to curb deterioration of the short channel characteristics. Similarly, if the channel semiconductor layer 15 containing Ti is oxidized a TiO_{X} film will be formed as an insulator on the surface of the channel semiconductor layer 15, making it possible to curb deterioration of the short channel characteristics.

The channel semiconductor layer 15 may contain B (boron) atoms, P (phosphorus) atoms, or As (arsenic) atoms in addition to metal atoms. The channel semiconductor layer 15 according to the present embodiment contains B atoms, P atoms, or As atoms at a concentration of, for example, between 1.0 × 10¹⁶ [atoms/cm³] and 1.0 × 10¹⁹ [atoms/cm³] (both inclusive). This makes it possible to adjust the threshold voltage of the memory cells in the three-dimensional semiconductor memory to an appropriate value.

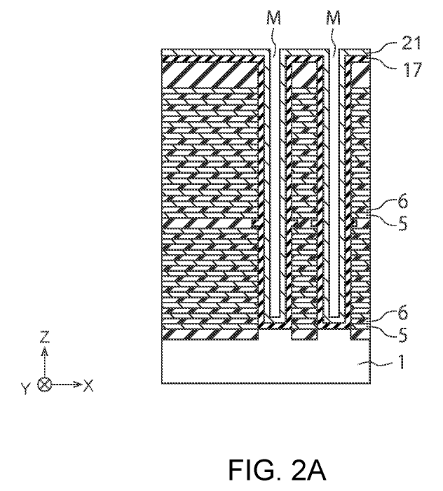

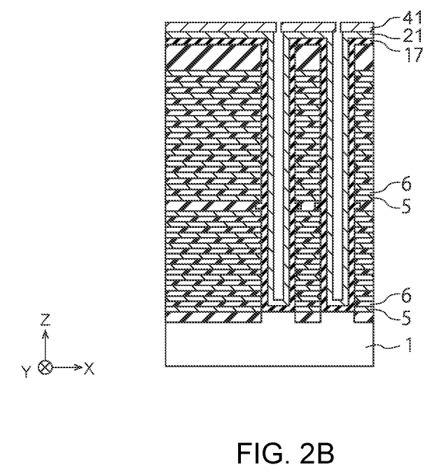

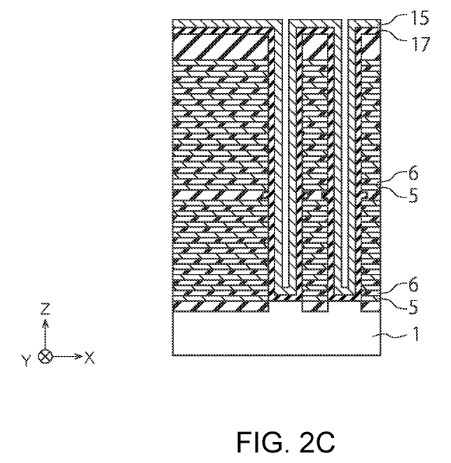

FIGS. 2A to 2C are cross-sectional views showing an example of a manufacturing method for the semiconductor storage device according to the first embodiment.

First, as shown in FIG. 2A, a stacked body is formed by stacking a plurality of the electrode layers 5 and a plurality of the insulation layers 6 alternately in the Z direction on the substrate 1. Then, the memory holes M are formed, penetrating through the stacked body in a first region in a Z-axis direction and reaching the substrate 1. Then, the memory film 17 (the block insulator 12, the charge trap layer 13, and the tunnel insulator 14) and the semiconductor layer 21 are formed in order on the lateral surfaces of the electrode layers 5 and insulation layers 6 in each of the memory holes M. The memory film 17 and the semiconductor layer 21 are also formed on an upper surface of a stacked structure made up of the electrode layers 5 and the insulation layers 6.

The semiconductor layer 21 is an amorphous semiconductor layer used to form the channel semiconductor layer 15 of FIG. 1, and is, for example, an amorphous silicon layer. The semiconductor layer 21 is formed, for example, by LPCVD (low pressure chemical vapor deposition) at a temperature of 400°C to 600°C and a pressure of 1 Pa to 500 Pa. Examples of source gas for the semiconductor layer 21 include SiH₄ gas, Si₂H₆ gas, SiH₂Cl₂ gas, Si₂Cl₆ gas, and organic gas containing Si (where H is hydrogen and Cl is chlorine). The film thickness of the tunnel insulator 14 is set, for example, to between 5 nm and 10 nm (both inclusive), and the film thickness of the semiconductor layer 21 is set, for example, to 15 nm or below (preferably 10 nm or below).

Note that in the process of FIG. 2A, instead of alternately stacking the plurality of electrode layers 5 and the plurality of insulation layers 6, a plurality of sacrificial layers and a plurality of the insulation layers 6 may be stacked alternately. The sacrificial layers are, for example, SiN films. In that case, the sacrificial layers are replaced by the electrode layers 5 in a downstream process. Specifically, the sacrificial layers among the insulation layers 6 are removed, forming a plurality of cavities among the insulation layers 6, and the electrode layers 5 are embedded in the cavities.

Next, as shown in FIG. 2B, a film 41 containing metal atoms is formed on the upper surface of the stacked structure made up of the electrode layers 5 and the insulation layers 6, i.e., on second regions of the stacked body in which the memory hole M is not provided. The film 41 is formed, for example, by PVD (physical vapor deposition) such as sputtering. The metal atoms are, for example, Ni atoms.

Next, as shown in FIG. 2C, the semiconductor layer 21 is annealed. The annealing is done, for example, at a temperature of 500°C to 1000°C and a pressure of 100 Pa to atmospheric pressure. As a result, metal atoms enter the semiconductor layer 21, and the semiconductor layer 21 is crystalized. FIG. 2C shows the channel semiconductor layer 15 changed from the semiconductor layer 21. The channel semiconductor layer 15 is, for example, a polysilicon layer. The annealing may be done in an atmosphere containing at least any of H₂ gas, D₂ (deuterium) gas, N₂ gas, and rare gas.

At least one crystal grain in the channel semiconductor layer 15 is shaped to contact the memory film 17. The crystal grain in the channel semiconductor layer 15 may be 65 nm or above in size and the channel semiconductor layer 15 may be monocrystalline.

According to the present embodiment, after annealing in the process of FIG. 2C, the channel semiconductor layer 15 may be further annealed at a temperature higher than in the annealing in the process of FIG. 2C. This will make it possible to increase the crystallinity of the channel semiconductor layer 15. The annealing may be done in an atmosphere containing at least any of H₂ gas, D₂ gas, N₂ gas, and rare gas.

Next, processes subsequent to the crystallization of the channel semiconductor layer 15 will be described.

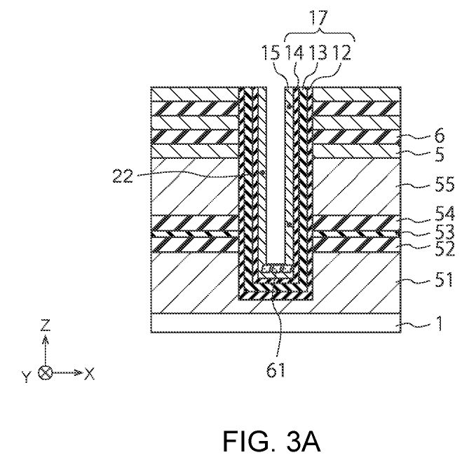

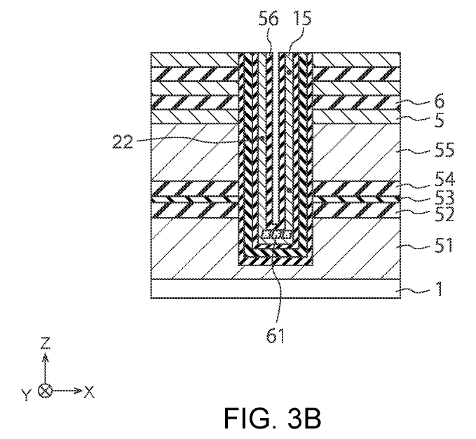

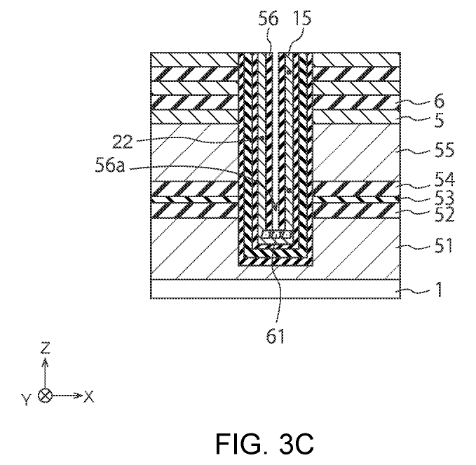

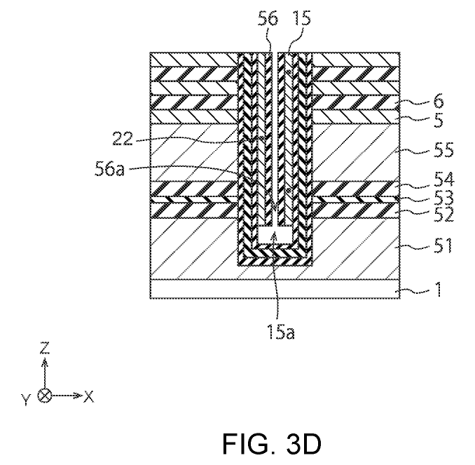

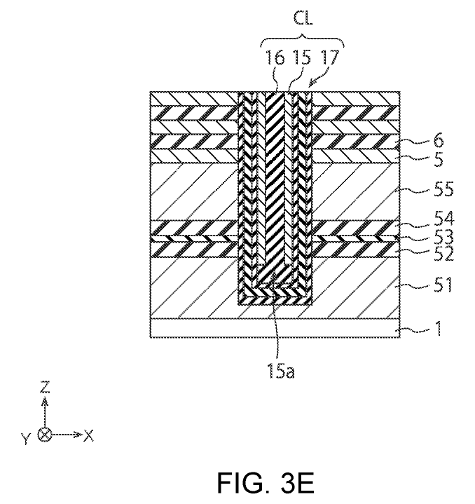

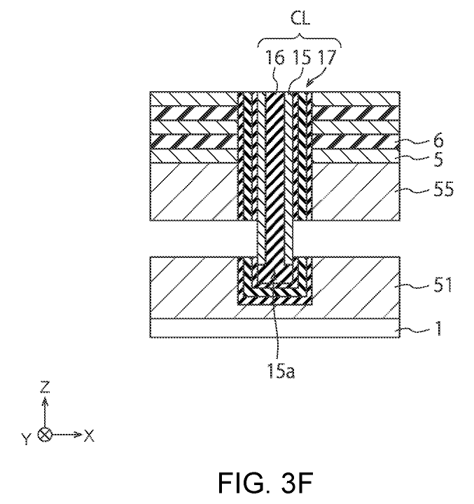

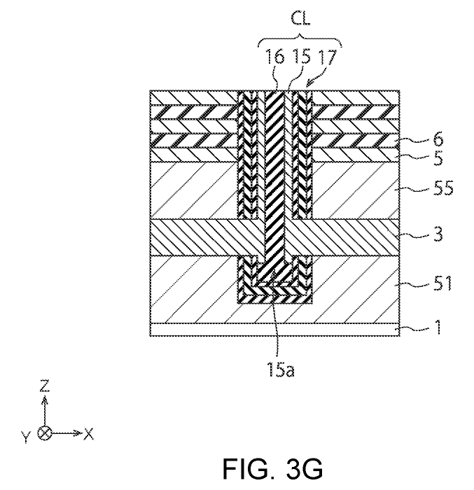

FIGS. 3A to 3G are cross-sectional views showing an example of a manufacturing method for the semiconductor storage device according to the first embodiment.

In the example shown in FIGS. 3A to 3G, a semiconductor layer 51, an intermediate film 52, a sacrificial film 53, an intermediate film 54, and a semiconductor layer 55 are provided on the substrate 1. The semiconductor layers 51 and 55 contain, for example, polysilicon. The intermediate films 52 and 54 include, for example, a silicon oxide film. The sacrificial film 53 includes, for example, a silicon nitride film.

First, as with FIG. 2C, the semiconductor layer 21 is crystalized by annealing as shown in FIG. 3A. After formation of the crystalized channel semiconductor layer 15, a compound 61 of metal atoms 22 and silicon accumulates (coheres) on the channel semiconductor layer 15 at the bottom of the memory hole M. The compound 61 is, for example, NiSi₂. Simple metal atoms 22 also exist in the channel semiconductor layer 15.

Next, as shown in FIG. 3B, a protective film 56 is formed on the channel semiconductor layer 15. The protective film 56 is, for example, a silicon oxide film. The protective film 56 protects the channel semiconductor layer 15 on the side of a wall in subsequent processes.

Next, as shown in FIG. 3C, an opening 56a is formed in the protective film 56 at the bottom of the memory hole M. The opening 56a is formed, for example, by RIE (reactive ion etching).

Next, as shown in FIG. 3D, part of the channel semiconductor layer 15 in the lower part of the memory hole M is removed. More specifically, part of the channel semiconductor layer 15 is removed through the opening 56a. Consequently, the channel semiconductor layer 15 in the lower part of the memory hole M is divided, forming an opening 15a in the channel semiconductor layer 15. The part of the channel semiconductor layer 15 is removed, for example, by wet etching. The compound 61 is removed together with the part of the channel semiconductor layer 15.

Next, as shown in FIG. 3E, the protective film 56 is removed, the core insulator 16 in which the memory hole M is to be embedded is formed, and gettering of the metal atoms 22 in the channel semiconductor layer 15 is done. The gettering is done, for example, by forming a getter layer (not shown) on the stacked body and annealing the getter layer. As a result, part of the metal atoms 22 in the channel semiconductor layer 15 moves to the getter layer, reducing the concentration (or total amount) of the metal atoms 22 in the channel semiconductor layer 15. The getter layer is, for example, an amorphous semiconductor layer, and specifically, an amorphous silicon layer.

Next, as shown in FIG. 3F, the intermediate film 52, the sacrificial film 53, and the intermediate film 54 are removed, and then the memory film 17 thus exposed is removed. Consequently, the channel semiconductor layer 15 is exposed.

Next, as shown in FIG. 3G, the source-side conductive layer 3 electrically connected with the channel semiconductor layer 15 is formed. The channel semiconductor layer 15 contacts the source-side conductive layer 3 on the lateral surface of the memory hole M. The source-side conductive layer 3 contains, for example, silicon. Note that the opening 15a in the channel semiconductor layer 15 does not affect the connection with the source-side conductive layer 3.

As shown in FIG. 3G, the semiconductor storage device includes a column CL. The column CL extends in the Z direction by penetrating through the stacked body made up of the electrode layers 5 and the insulation layers 6. The column CL includes the memory film 17, the channel semiconductor layer 15, and the core insulator 16 embedded in the memory hole M. The channel semiconductor layer 15 extends in the Z direction by penetrating through the stacked body made up of the electrode layers 5 and the insulation layers 6. The memory film 17 is provided between the channel semiconductor layer 15 and the stacked body made up of the electrode layers 5 and the insulation layers 6. The memory film 17 is provided along the bottom surface of the memory hole M.

The channel semiconductor layer 15 has the opening 15a at the end of the column CL. The core insulator 16 is provided penetrating through the opening 15a in the channel semiconductor layer 15.

The source-side conductive layer 3 is electrically connected with the channel semiconductor layer 15 at the end of the column CL. More specifically, the channel semiconductor layer 15 contacts the source-side conductive layer 3 on a lateral surface at the end of the column CL.

As described above, according to the first embodiment, as a result of crystallization using the film 41 containing metal atoms, the channel semiconductor layer 15 is formed with a relatively large grain size of crystal grains. Besides, removal of the compound 61 by etching and gettering of the metal atoms 22 reduce the concentration of the metal atoms 22 in the channel semiconductor layer 15. This makes it possible to increase the mobility of the channel semiconductor layer 15 while reducing the leakage current in the tunnel insulator 14 or otherwise improve the characteristics of the channel semiconductor layer 15.

Besides, according to the first embodiment, the compound 61 can be removed by directly etching the channel semiconductor layer 15 containing the compound 61. This makes it possible to increase gettering efficiency for the metal atoms 22 and the compound 61.

Another example of removing the compound 61 may involve pyrolyzing the compound 61 into the metal atoms 22 by annealing, segregating the compound 61 on the getter layer, and striping off the getter layer. However, the distance to the getter layer increases with increases in the height of the stacked body made up of the electrode layers 5 and the insulation layers 6. Besides, the more sharply the bottom of the memory hole M is tapered, the more densely the compound 61 coheres. This makes it difficult to pyrolyze the compound 61 accumulating at the bottom of the memory hole M, which might reduce the gettering efficiency. This makes it necessary to do gettering at a higher temperature, for a longer time, or multiple times. Consequently, diffusion of the metal atoms 22 could increase the concentration of residual metal atoms 22 and deteriorate cell characteristics.

In contrast, according to the first embodiment, the compound 61 can be removed by directly etching the channel semiconductor layer 15 containing the compound 61. This makes it possible to increase the gettering efficiency for the metal atoms 22. It becomes also possible to do gettering using a body thin film of the channel semiconductor layer 15. Besides, reduction in the number of processes can lead to cost reduction.

### Modification of first embodiment

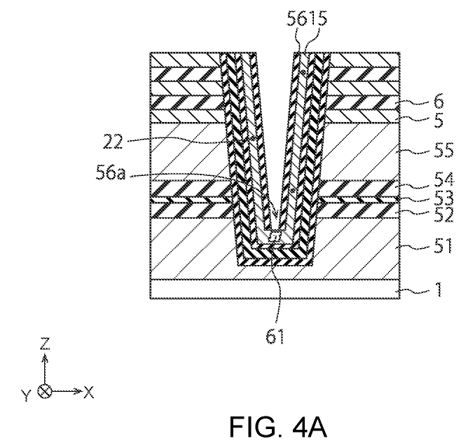

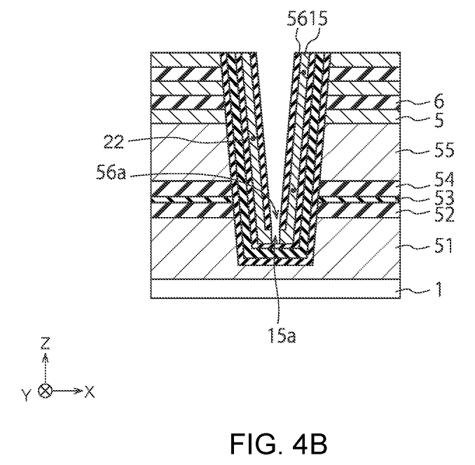

FIGS. 4A and 4B are cross-sectional views showing an example of a manufacturing method for a semiconductor storage device according to a modification of the first embodiment. The modification of the first embodiment differs from the first embodiment in that the memory hole M has a tapered shape.

The process shown in FIG. 4A is performed after processes similar to those shown in FIGS. 2A to 2C, FIG. 3A, and FIG. 3B. The process shown in FIG. 4A corresponds to the process shown in FIG. 3C of the first embodiment in which the opening 56a is formed.

When the memory hole M has a tapered shape as shown in FIG. 4A, the compound 61 tends to cohere (at a relatively high density) in a relatively small area at the tip of the memory hole M.

Next, as shown in FIG. 4B, part of the channel semiconductor layer 15 in the lower part of the memory hole M is removed. Consequently, the opening 15a is formed in the channel semiconductor layer 15. Part of the channel semiconductor layer 15 is removed, for example, by dry etching. The compound 61 is removed together with the part of the channel semiconductor layer 15.

The channel semiconductor layer 15 is removed by dry etching in a small area in which the compound 61 coheres.

Subsequently, processes similar to FIG. 3E and subsequent processes of the first embodiment are carried out.

As with the modification of the first embodiment, the memory hole M may have a tapered shape. The semiconductor storage device according to the modification of the first embodiment provides advantages similar to those of the first embodiment.

### Second embodiment

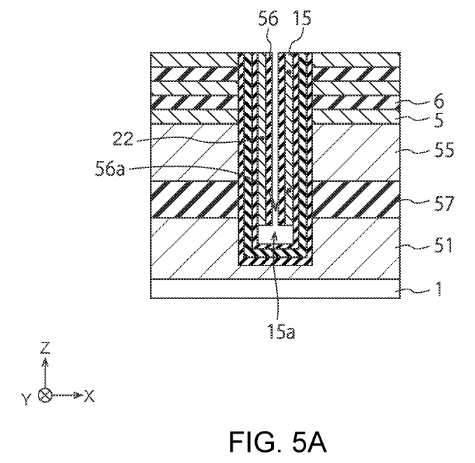

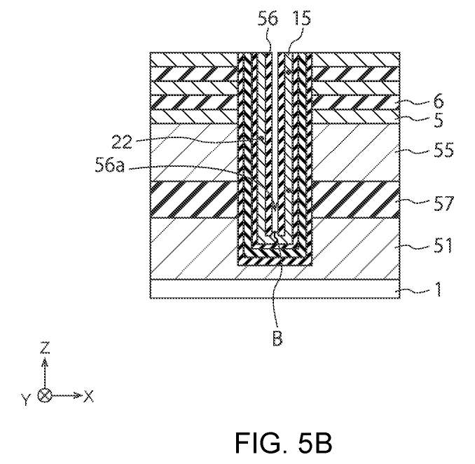

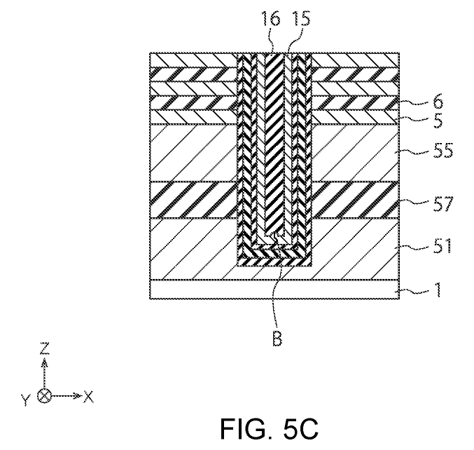

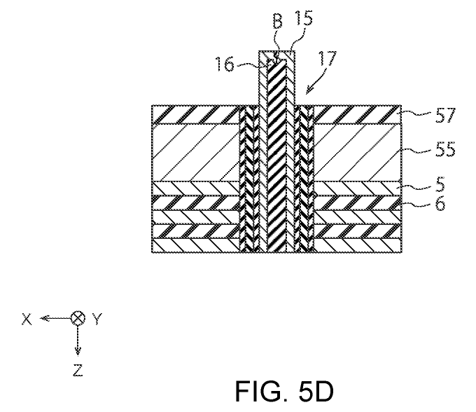

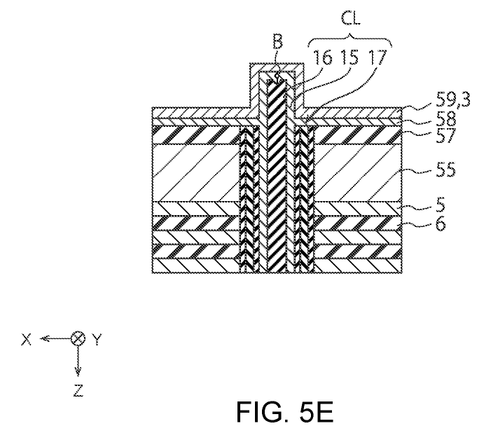

FIGS. 5A to 5E are cross-sectional views showing an example of a manufacturing method for a semiconductor storage device according to a second embodiment. The second embodiment differs from the first embodiment in that the channel semiconductor layer 15 contacts the source-side conductive layer 3 on an end face of the column CL.

The process shown in FIG. 5A is performed after processes similar to those shown in FIGS. 2A to 2C and FIGS. 3A to 3C. The process shown in FIG. 5A corresponds to the process shown in FIG. 3D of the first embodiment in which part of the channel semiconductor layer 15 in the lower part of the memory hole M is removed. Note that an intermediate film 57 is provided instead of the intermediate film 52, the sacrificial film 53, and the intermediate film 54.

Next, as shown in FIG. 5B, silicon of the channel semiconductor layer 15 is epitaxially grown. A monocrystal of the channel semiconductor layer 15 grows along the memory film 17 from the respective directions of edges of the opening 15a. That is, the monocrystal of the channel semiconductor layer 15 grows along the lateral surfaces and bottom surface of the memory hole M. As a result, the channel semiconductor layer 15 is reconnected at the bottom of the memory hole M, blocking up the opening 15a. A grain boundary B of the channel semiconductor layer 15 corresponds to the reconnected part. That part of the channel semiconductor layer 15 which is around the grain boundary B may contain crystal grains of relatively large grain size or may be monocrystalline.

In the reconnected part of the channel semiconductor layer 15 in which the grain boundary B is formed, the channel semiconductor layer 15 does not necessarily have to be connected neatly, and may have a swollen shape. That is, that part of the channel semiconductor layer 15 in which the grain boundary B exists (that part of the channel semiconductor layer 15 which is around the grain boundary B) may be thicker than other part of the channel semiconductor layer 15.

Next, as shown in FIG. 5C, the protective film 56 is removed, the core insulator 16 in which the memory hole M is to be embedded is formed, and gettering of the metal atoms 22 in the channel semiconductor layer 15 is done. The process shown in FIG. 5C is the same as the process shown in FIG. 3E.

Next, as shown in FIG. 5D, the substrate 1 is stripped off and part of the memory film 17, the semiconductor layer 51, and part of the intermediate film 57 are removed from the bottom side of the memory hole M. Note that the semiconductor layer 51 has been totally removed. The core insulator 16, which is covered with the channel semiconductor layer 15 serving as a protective layer, is not removed.

Next, as shown in FIG. 5E, a semiconductor layer 58 is formed on the memory film 17 and the intermediate film 57, and a conductive layer 59 is formed on the channel semiconductor layer 15 and the semiconductor layer 58. The conductive layer 59 functions as the source-side conductive layer 3. The semiconductor layer 58 contains, for example, amorphous silicon. The conductive layer 59 contains, for example, W (tungsten).

As shown in FIG. 5E, the channel semiconductor layer 15 contacts the source-side conductive layer 3 at the bottom of the memory hole M (on the end face of the column CL).

The channel semiconductor layer 15 has the grain boundary B at the end of the column CL.

As with the second embodiment, the channel semiconductor layer 15 may contact the source-side conductive layer 3 on the end face of the column CL. The semiconductor storage device according to the second embodiment provides the same advantages as the first embodiment. The semiconductor storage device according to the second embodiment may be combined with the modification of the first embodiment.

Note that in the first embodiment, the grain boundary B may be formed instead of the opening 15a.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor storage device comprising:
a stacked body made up of a plurality of first conductive layers stacked in a first direction via an insulation layer; and
a column extending in the first direction by penetrating through the stacked body, wherein:
the column includes
a semiconductor layer extending in the first direction by penetrating through the stacked body, and
a memory film that includes a first insulator, a charge trap layer, and a second insulator provided between the stacked body and the semiconductor layer,
the semiconductor storage device further comprises a second conductive layer electrically connected with the semiconductor layer at an end of the column,
at least one crystal grain in the semiconductor layer is shaped to contact the memory film,
the semiconductor layer has a first opening at the end of the column or a grain boundary exists in the semiconductor layer at the end of the column.

2. The semiconductor storage device according to claim 1, wherein that part of the semiconductor layer in which the grain boundary exists is thicker than other part of the semiconductor layer.

3. The semiconductor storage device according to claim 1, wherein grain size of crystal grains in the semiconductor layer is 65 nm or above, or the semiconductor layer is monocrystalline.

4. The semiconductor storage device according to claim 1, wherein:
the column further includes a third insulator extending in the first direction by penetrating through the stacked body;
the semiconductor layer is provided, surrounding the third insulator; and
the third insulator is provided, penetrating through the first opening in the semiconductor layer.

5. The semiconductor storage device according to claim 1, wherein the semiconductor layer contacts the second conductive layer on a lateral surface at the end of the column.

6. The semiconductor storage device according to claim 1, wherein the semiconductor layer contacts the second conductive layer on an end face of the column.

7. The semiconductor storage device according to claim 3, wherein that part of the semiconductor layer in which the grain boundary exists is thicker than other part of the semiconductor layer.

8. The semiconductor storage device according to claim 5, wherein that part of the semiconductor layer in which the grain boundary exists is thicker than other part of the semiconductor layer.

9. The semiconductor storage device according to claim 6, wherein that part of the semiconductor layer in which the grain boundary exists is thicker than other part of the semiconductor layer.

10. The semiconductor storage device according to claim 4, wherein the semiconductor layer contacts the second conductive layer on a lateral surface at the end of the column.

11. A manufacturing method for a semiconductor storage device, the method comprising:
forming a stacked body made up of a plurality of first conductive layers stacked in a first direction via an insulation layer;
forming a hole extending in the first direction by penetrating through the stacked body in a first region;
forming a memory film that includes a first insulator, a charge trap layer, and a second insulator in the hole;
forming a semiconductor layer on the memory film;
forming a first film containing metal atoms on the stacked body in a second region;
annealing and thereby crystallizing the semiconductor layer; and
removing part of the semiconductor layer at a bottom of the hole.

12. The manufacturing method for a semiconductor storage device according to claim 11, wherein removing part of the semiconductor layer at a bottom of the hole includes:
forming a second film on the semiconductor layer;
forming a second opening in the second film at the bottom of the hole; and
removing part of the semiconductor layer through the second opening.
